(19) United States
(12) Patent Application Publication
(10) Pub. No.: US 2008/0128872 A1
(43) Pub. Date: Jun. 5, 2008

(54) SEMICONDUCTOR DEVICE AND METHOD FOR PRODUCING A SEMICONDUCTOR DEVICE

(75) Inventor: Joerg Schepers, Rottach-Egern (DE)

Correspondence Address: INFINEON TECHNOLOGIES AG;Patent Department, MUC 11.1.507, P.O. Box 221644, Munich, 80506, omitted

(73) Assignee: INFINEON TECHNOLOGIES AG, Muenchen (DE)

(21) Appl. No.: 11/947,795

(22) Filed: Nov. 30, 2007

(30) Foreign Application Priority Data
Dec. 1, 2006 (DE) 10 2006 056 878.8
May 22, 2007 (DE) 10 2007 023 666.4

(51) Int. Cl. H01L 23/58; H01L 21/44

(52) U.S. Cl. 257/664; 438/599; 257/E23.019; 257/E21.575

(57) ABSTRACT

The disclosure relates to a semiconductor device and a method for producing a semiconductor device, in particular a semiconductor device having a circuit region having at least one active component for processing a high-frequency electromagnetic signal.

### FIELD OF THE INVENTION

Embodiments of the present disclosure relates to a semiconductor device and a method for producing a semiconductor device, in particular a semiconductor device having a circuit region having at least one active component for processing a high-frequency electromagnetic signal.

### BACKGROUND

A semiconductor device, such as e.g. a silicon chip, is provided usually with a housing, which is also referred to as a ‘package’. The package serves to protect the semiconductor device against external damage. Moreover, it serves to spread the heat generated by the semiconductor device efficiently over the package structure in order to ensure disturbance-free operation of the semiconductor device.

In a conventional package, the semiconductor device is applied on a support carrier, such as a laminate or a substrate. Depending on the type of package, the electrical contact areas (pads) of the silicon chip are connected to the substrate by means of thin gold wires. This package type is referred to as a ‘wire-bonding package’. In another type of package, the silicon chip is soldered onto the contact area of the laminate with its top surface (i.e. with the topmost metal layer), as it were face down, by means of so-called bumps. This type of package is referred to as a ‘flip-chip package’. The two package variants have disadvantages when used for semiconductor devices, which serve for signal processing of a high-frequency electrical signal.

In the case of the wire-bonding package, the thin gold wires act as antennas and therefore have influence high frequency signals conducted via them. A bonding wire forms an inductive reactance for the signal itself. Adjacent small gold wires may cause crosstalk effects. Cross talk effects involve signals that are conducted via one of said bonding wires coupling over to adjacent bonding wires. Thus, adjacent signal paths in the circuit structure of the device may be affected. The usage of wire bonding may cause additional problems. The non-reactive resistances and, in particular at high frequencies, the inductive reactance of the bonding wire itself has a disadvantageous effect on the ground coupling of the device. Yet, the ground coupling constitutes a prerequisite for reliable operation of a high-frequency device. Furthermore, bonding wires are additionally disadvantageous in terms of production engineering since, because of their precision-mechanical properties, they are susceptible with regard to production faults and often constitute the cause of reliability problems. Moreover, the thin bonding wires may break easily or be connected defectively onto the laminate. The bonding wires contribute significantly to the structural height of a package; particularly by virtue of the fact that a wire-bonding package must always be coated with a plastic in order to protect the sensitive bonding wires.

In the case of the flip-chip package, the semiconductor device is soldered onto a single- or multilayer laminate by its electrically active side. This type of package avoids some of the disadvantages resulting from the wire-bonding package. E.g. inductively active bonding wires are not used. Yet, in the laminate itself, coupling effects still occur because of inductive and capacitive couplings between line routings laid in the laminate and contact holes. This causes a lasting adverse influence on the high frequency properties of the device. Such laminates are relatively expensive, as is the process for producing such package. In addition, the structural height of the package is still big, by the relatively thick laminates.

### BRIEF DESCRIPTION OF THE DRAWINGS

The detailed description is described with reference to the accompanying figures. The use of same reference numbers in different instances in the description and the figures may indicate similar or identical items.

FIG. 1 shows a schematic illustration of an implementation of a semiconductor device with a wafer level package.

FIG. 2 shows a view of the cross section through the semiconductor device shown in FIG. 1 along an axis 103.

FIG. 3a to FIG. 3e show a view through a cross section of the semiconductor device during a process for producing the semiconductor device shown in FIG. 1.

FIG. 4 shows a schematic illustration of an implementation of a modulator or a demodulator.

FIG. 5 shows a schematic illustration of an implementation of a power amplifier.

### DETAILED DESCRIPTION

Disclosed herein is semiconductor device semiconductor device having a circuit region having at least one active component for processing a high-frequency electromagnetic signal.

In one described embodiment the semiconductor device has a substrate, e.g. a semiconductor body, having an active surface and a second surface. A circuit region having at least one active component for processing a high-frequency electromagnetic signal is formed in the substrate. A pad opening layer is applied on the active surface of the substrate, said pad opening layer having an opening to a pad of the substrate. A contact distributor layer is applied over the opening and the pad opening layer, said contact distributor layer being formed partly on the opening and being electrically connected to the pad. A passivation layer is applied on the contact distributor layer, said passivation layer having a second opening on a section of the contact distributor layer. A contact is arranged on the second openings, said contact being electrically connected to the section of the contact distributor layer.

A described embodiment provides a high-frequency device, which has a so-called ‘wafer level h package’. The use of a wafer level package makes it possible to enable the complete development and in particular the simulation of the semiconductor device without interfering parasitic effects due to additional housing components. Thus, the development cycles may be significantly shortened due to lack of parasitic effects. A smaller structural height of the semiconductor device is made possible, and the overall size of the device is minimized. An additional advantage is that dissipation of thermal energy arising during operation in the semiconductor device is also improved. Energy can be dissipated directly to the surroundings via the uncovered chip rear side.

Furthermore, parasitic coupling effects of the high-frequency electromagnetic signal are reduced by the use of said wafer level package. It should be noted that the term wafer level package is misleading in so far as a package enclosing the semiconductor body is not actually provided. Only the topmost metallization layer is covered with a material. A carrier material such as a laminate or a substrate is dispensed with, such that the contacts of the package are applied to the pad of the silicon chip directly or via the contact distributor layer.

In one described embodiment a method according for producing the semiconductor device is provided. It comprises the following steps of:
Providing a semi-conductor substrate having an active surface and a passive surface,
Patterning a circuit region in the substrate, wherein the circuit region has at least one active component for processing a high-frequency electromagnetic signal,
Forming a pad opening layer having an opening over a pad of the substrate,
Forming a contact distributor layer, which extends at least partly on the opening of the pad opening layer,
Forming a passivation layer having a second opening over a section of the contact distributor layer,
applying a contact on the second opening.

### Exemplary System

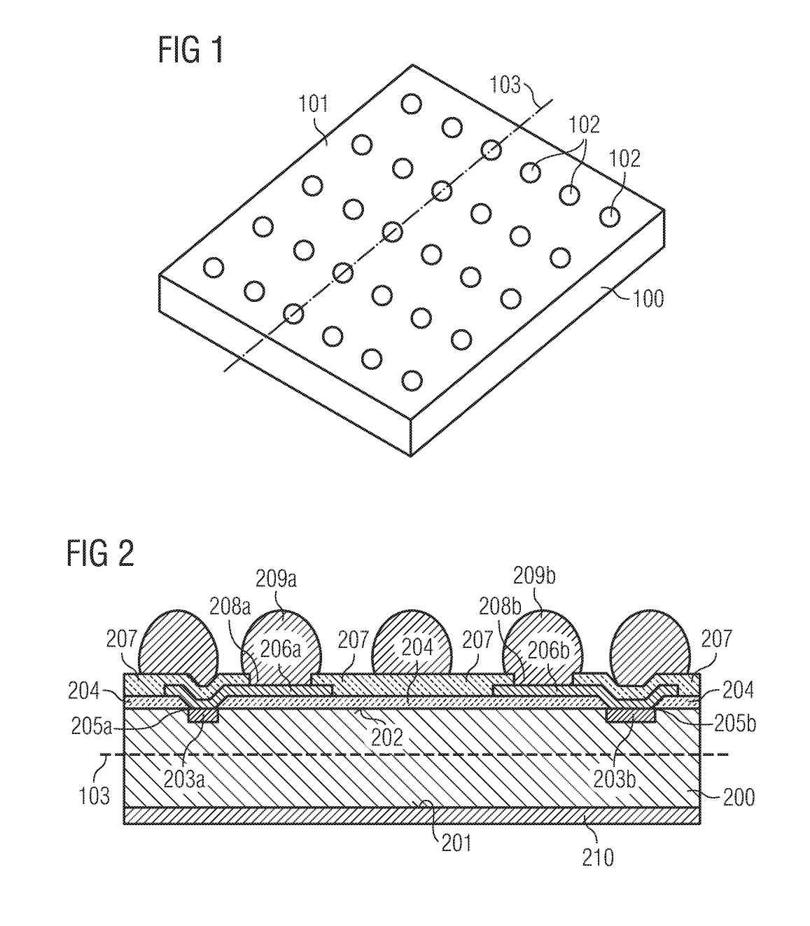

FIG. 1 shows the schematic illustration of a semiconductor device with a wafer level package. The semiconductor device has a semiconductor substrate 100, e.g. a silicon body. The semiconductor substrate 100 is patterned by a semiconductor process such as a CMOS process or a Bipolar process. It has an active surface 101, on which contacts 102, e.g. formed by solder balls, are arranged.

FIG. 2 shows a view of the cross section through the semiconductor device shown in FIG. 1 along an axis 103.

A semiconductor substrate 200 is illustrated, having a passive surface 201 and an active surface 202. A circuit region having at least one active component for processing a high-frequency electromagnetic signal is formed in the semiconductor substrate 200. The circuit structure is not illustrated in FIG. 2 for the sake of simplicity. The active component may be an amplifier, an analog-to-digital converter, a digital to analog-converter, a mixer, or any other circuitry, part of circuitry, etc.

Pads 203a, 203b serving for contact-connecting the circuit region with an external connection are provided in the topmost metallization layer of the substrate 200. The topmost metallization layer corresponds e.g. to a sixth, seventh or eighth metallization layer, depending on a processing used. The semiconductor substrate 200 is e.g. silicon, GaAs, or some other semiconductor. The circuit region in the semiconductor substrate 200 may be formed by means of a CMOS technology, a bipolar technology, or any other conceivable technology for producing or for patterning active components. The semiconductor substrate 200 has typically been thinned by a thinning out and has a thickness of 50 μm to 100 μm.

A pad opening layer 204 is arranged on the active surface 202 of the semiconductor substrate 200, said pad opening layer 204 being produced for example from a thermally curing material, such as BCB, epoxy resin, etc. The pad opening layer 204 is patterned such that it has openings 205a, 205b over the respective pads 203a, 203b. The pad opening layer 204 may have a thickness of 6 μm. However, it is likewise conceivable for the pad opening layer 204 to be made thinner or thicker.

A contact distributor layer 206a, 206b is formed on the pad opening layer 204 and the openings 205a, 205b. The contact distributor layer 206a, 206b is also referred to as redistribution layer. It comprises materials such as TiW Cu, the material being applied by means of a sputtering technique. In other embodiments it may comprise a CU—Ni—Cu material applied by an electroplating, for example. Other materials may be applied as well. The contact distributor layer 206a, 206b is arranged in such hat it is in electrical contact with the pads 203a, 203b. In the exemplary embodiment shown, it has a thickness of 6 μm, but other thicknesses are also conceivable, e.g. also of 50 nm or 150 nm.

An insulating and/or passivation layer 207 is provided on the contact distributor layer 206a and 206b. The passivation layer 207 has a layer thickness of 11 μm and can be produced from a polyamide like the pad opening layer 204. The layer thickness may vary depending on technical needs. Second openings 208a, 209a are patterned in the passivation layer 207 so to enable a external connection to the contact distributor layer 205a, 205b. Solder balls 209a, 209b are respectively arranged on the second openings 208a, 208b. The solder balls 209a, 209b are part of a multiplicity of solder balls 102 as shown e.g. in FIG. 1. They comprise a solder material such as e.g. SnAgCu. Their diameter is e.g. 250 μm, and the diameter decreases to approximately 200 μm after mounting. The solder balls 209a, 209b serve as input and output contacts of the semiconductor device. They are connected via the contact distributor layer 206a, 206b to the pads 203a, 203b of the circuit region arranged in the substrate. Consequently, the circuit region provided in the substrate 200 is electrically accessible externally.

The embodiment illustrated in FIG. 2 shows a so-called fan-in structure of the wafer level package, in which the area covered by solder balls 209a, 209b corresponds to the surface of the semiconductor substrate 200. It would likewise be conceivable for a so-called fan-out structure to be chosen, in which the area covered by solder balls 209a, 209b is greater than the surface of the semiconductor substrate 200. In this case, the contact distributor area 206a, 206b is patterned correspondingly. A fan-out structure would allow arranging a large contact surface on a small semiconductor device.

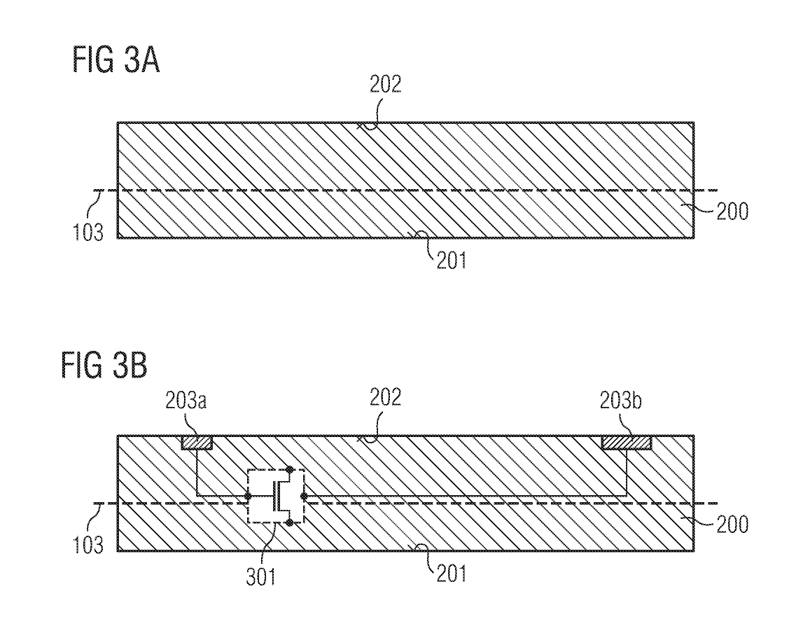

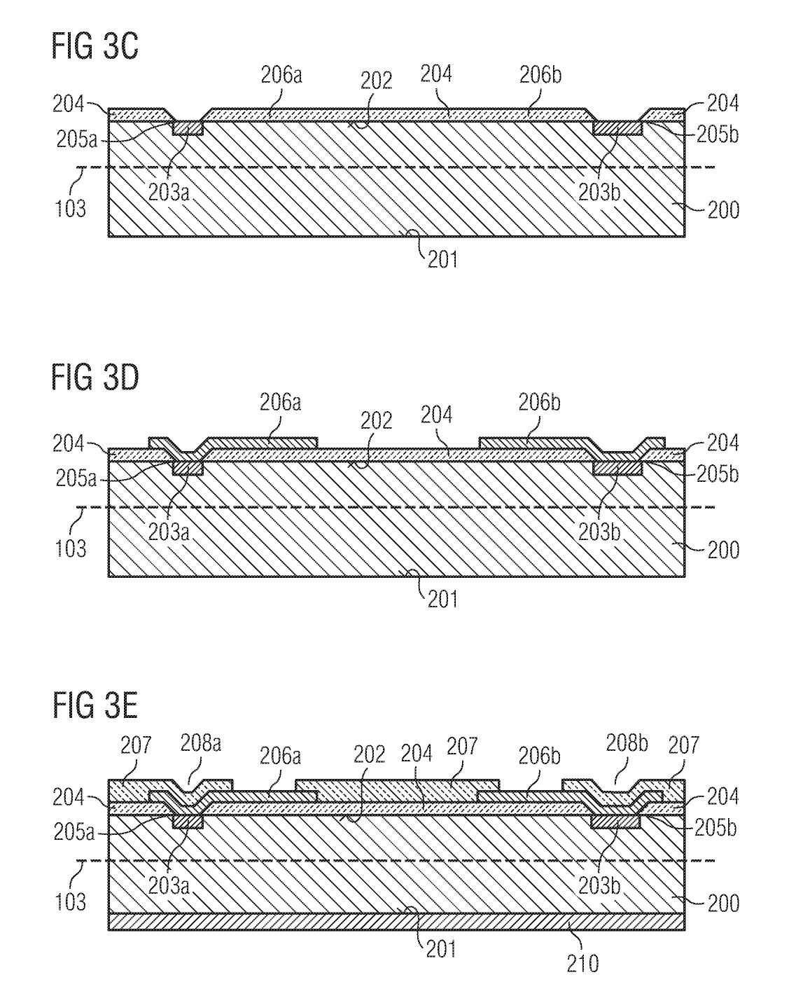

FIG. 3a to FIG. 3e show a view through a cross section of the semiconductor device during a process for producing the semiconductor device shown in FIG. 1.

FIG. 3a shows a semiconductor substrate 200, which comprises a semiconductor material, such as silicon. The semiconductor substrate 200, or such a wafer usually has a thickness of approximately 800 μm.

FIG. 3b shows that a circuit region is patterned in the semiconductor substrate 200. The circuit region comprises at least one active component, which is illustrated schematically by a transistor element 301 in the drawing. The circuit region has pads 203a, 203b comprising for example a material such as AlCu. The patterning of the substrate can be produced by known technologies in accordance with a CMOS process or bipolar process or further known semiconductor patterning processes. The circuit region is accessible externally through the pads 203a, 203b.

In a next step—as illustrated in FIG. 3b—a pad opening layer 204 is patterned on the semiconductor substrate 200, wherein firstly a dielectric material is applied to the semiconductor substrate 200. Said dielectric material can be for example a polyamide, such as an epoxy resin or BCB. A partial region of the dielectric material is subsequently removed by using a photomask above the pads 203a, 203b in order to form openings 205a, 205b in the pad opening layer 204.

In a further step—as illustrated in FIG. 3c—a contact distributor layer 206a, 206b is applied over the openings 205a, 205b and sections of the pad opening layer 204. The contact distributor layer 206a, 206b comprises TiW Cu or CuNi Cu, for example. The pad opening layer 204 may be formed by a sputtering technology, by electrodeposition, electroplating, or other suitable physical or chemical methods or by a combination thereof. The contact distributor layer 206a, 206b may be patterned by using a photomask.

In yet a further step, a passivation layer 207 is arranged over the contact distributor layer 206a, 206b. Said passivation layer 207 comprises a second dielectric material. The second dielectric material can be chosen in a manner similar to the dielectric material of the pad opening layer 204. In one embodiment, both the pad opening layer 204 and the passivation layer 207 are chosen to be very thin, so to achieve a thin layer package of the semiconductor substrate 200. The materials typically have a layer thickness of less than 12 μm. The second dielectric material is subsequently patterned through a photomask, such that the passivation layer 207 has openings 208a, 208b over the contact distributor layer 206a, 206b.

As illustrated in FIG. 3e, the semiconductor substrate 200 is subsequently processed by thinning out the passive rear side 201. Thinning out may be achieved by lapping back or grinding for the semiconductor substrate 200. The thickness of the semiconductor substrate 200 after thinning out is between 20 μm and 700 μm; a possible value is e.g. 450 μm. The processed silicon wafer can thus be sawn more easily during production with the abovementioned thicknesses.

A protective layer 210 is subsequently applied to the passive side 201 of the semiconductor substrate 200, said protective layer comprising for example a polyamide such as epoxy resin. However, the protective layer 210 is optional and may be omitted.

Solder balls 209a, 209b are positioned on the second openings 208a, 208b in the passivation layer 207, the solder balls 209a, 209b being connected to the areas of the contact distributor layer 206a, 206b by an IR fusion, for example.

The semiconductor device illustrated in FIG. 2 results as product of the shown processing. This embodiment is disposed such that the solder balls 209a, 209b are connected to the pads 203a, 203b via a redistribution layer, i.e. the contact distributor layer 206a, 206b. However, it is likewise conceivable for the solder balls 209a, 209b to be arranged directly on the pads 203a, 203b. In this case, the size of the pads 203a, 203b should be adapted to the size of the solder balls 209a, 209b and the required redistribution wiring is performed directly in the topmost metal layer of the circuit region. The passivation layer 207 and the contact distributor layer 206a, 206b are dispensed with in this embodiement. It is furthermore conceivable for the pad opening layer 204 to be dispensed with. It is likewise conceivable for the passivation layer 207 to be dispensed with or for a mixed form of the configurations mentioned to be provided as wafer level package of the semiconductor device.

The semiconductor substrate 200 has a circuit region having at least one active component for processing a high-frequency electromagnetic signal. By way of example, the substrate may comprise a transceiver circuit, a receiver circuit or a transmitter circuit for a cordless or wireless data transmission. It is likewise conceivable for the semiconductor substrate 200 to have a circuit region suitable for signal processing in a cord-base or wireline communication system. A further possibility is for the circuit region to have a power amplifier or an amplifier unit for amplifying a high-frequency electromagnetic signal.

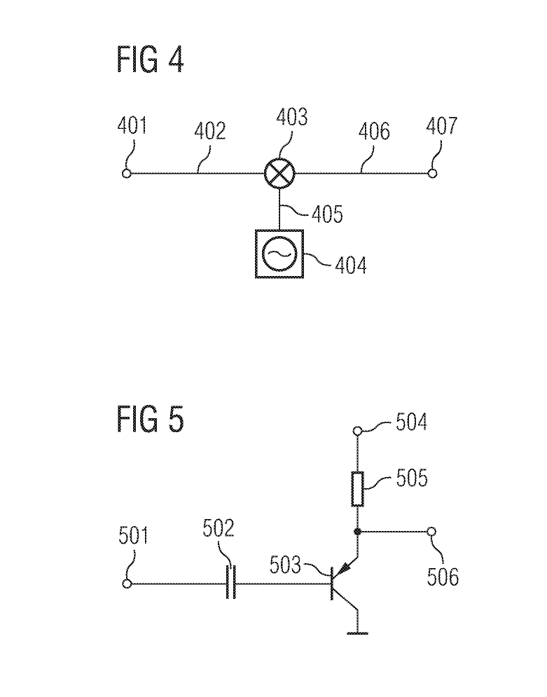

FIG. 4 illustrates a modulator such as used in an analogue modulation of a signal onto a carrier signal. The modulator has an input 401, which is connected to the first input of a mixer 403 via a line 402. A transmission signal may be fed in at the input. The modulator furthermore has a frequency generator 404, which is connected to a second input of the mixer 403 via a second line 405. The frequency generator 404 generates a carrier frequency signal lying in a specific frequency range depending on the transmission standard used. The mixer 403 has an output connected to an output 407 via a third line 406. The transmission signal is multiplied by a carrier frequency in the mixer 403, said carrier frequency being provided by the frequency generator 404. As a result, a signal, which both contains the information of the transmission signal and is modulated onto the carrier frequency of the carrier signal is transmitted at the output 407.

The frequency generator 404 can be provided in various configurations. By way of example, a so-called phase locked loop (PLL) or an oscillator controlled by voltage, current or a digital signal is conceivable. It is likewise conceivable for the frequency generator 404 to comprise a quartz crystal. Further conceivable frequency generators are for example ring generators or resonant circuits.

A signal in baseband containing the information to be transmitted for example through a phase or amplitude modulation is provided at the input 401. The baseband signal is modulated by the modulation into the frequency range of the transmission system. The modulation as shown permits a transmission over large distances, the range and quality of the transmission essentially being influenced by the frequency of the carrier signal. In this case, frequencies of 400 MHz or in a range of 900 to 1800 MHz are allowed for example for a GSM radio system. Frequencies of between 2 and 2.5 GHz are chosen in a transmission system, which operates in the so-called ISM band, while frequencies in the range of 3.5 to 5 GHz can be chosen in radio transmission systems such as, for example, wireless local area networks (WLAN) or Wimax. It is possible for a transmitting functionality and a receiving functionality to be combined in one device, a so-called transceiver device. These can additionally also be operated simultaneously as in the mobile radio standard UMTS, for example, wherein transmitting and receiving is performed at different frequency bands. The relatively strong transmission signal can influence the input signal received very sensitively in this case. New types of transceivers additionally have a multiplicity of inputs and outputs for different frequency bands and different mobile radio standards, such that the number of possible interactions between said inputs and outputs increases exponentially.

Therefore, it is advantageous if the influence of parasitic package effects is reduced by the use of the wafer level package, as described in the present disclosure. This is all the more desirable since modern systems also attempt to carry out a baseband signal processing alongside a signal processing of high-frequency analogue signals. Such single chips are produced for example using CMOS technologies. In this case, too, it is important to reduce as far as possible parasitic effects as a result of lines in the package.

FIG. 5 shows the embodiment of a circuit region in the substrate of the semiconductor device as a power amplifier. The power amplifier has an input 501 serving for taking up a high-frequency input signal. The input 501 couples to a base terminal of a transistor 503 via a capacitance 502. A pure AC coupling to the base terminal of the transistor 503 takes place through the provision of the capacitor 502. Furthermore, the power amplifier has a supply voltage input 504, which couples to an emitter terminal of the transistor 503 via an impedance 505. The impedance 505 can be for example an inductance or a nonreactive resistance. A collector terminal of the transistor 503 couples to a ground terminal or to a reference potential terminal. The emitter terminal of the transistor 503 couples to an output 506 of the power amplifier. The emitter circuit comprising the transistor 503 amplifies an input signal provided at the input 501. A correspondingly amplified signal is provided at the output 506. The embodiment of FIG. 5 shows the transistor 503 to be disposed as a bipolar transistor, but it is likewise conceivable for the circuitry to be produced in a CMOS technology or in any other known semiconductor technology. It is likewise possible to provide other circuits of the power amplifier with active components.

Parasitic effects are extremely critical precisely if the circuit region in the semiconductor substrate 200 comrises a power amplifier. This is due to the relatively high output power at the output 506 of the power amplifier, leading to a severe crosstalk of the signals at other circuit parts in the semiconductor device. The use of the wafer level package in the case of a power amplifier is advantageous because dissipation of the thermal energy that arises during operation is greatly improved if energy can be dissipated via the uncovered chip rear side or via the uncovered chip surface directly to the surroundings. Overall, the wafer level package thus offers a major advantage over conventional package forms. By way of example, the structural height of the semiconductor device is considerably reduced since the layers applied on the substrate are significantly thinner than the laminations or encapsulations of normal package technologies. Cost and reliability problems of the known packages are avoided, and costs can moreover be saved, since, with carrier materials being dispensed with, the solder balls of the wafer level package are applied directly on the pads of the silicon chip. Structural height is a property which represents a significant product feature particularly in the mobile radio sector. The current trend is moving further and further towards very flat mobile devices, for which a small construction height of the packaged semiconductor devices is a desired prerequisite.

Other circuits, such as low noise amplifiers, switches, filters, duplexers, amplifiers in general, power control units, DC/DC converters, etc. are also conceivable to be arranged in the circuit region.

### Conclusion

For the purposes of this disclosure anf the claims that follows, the terms “coupled” and “connected” have been used to describe how various elements interface. Such described interfacing may be either direct or indirect. Although the subject matter has been described in language specific to structural features and/or methodological acts, it is to be understood that the subject matter defined in the appended claims is not necessarily limited to the specific features or acts described. Rather, the specific features and acts are disclosed as preferred forms of implementing the claims.

What is claimed is:

1. A semiconductor device comprising:
a substrate having an active surface, a second surface, and a pad arranged at the active surface,
a circuit region provided in the substrate, having at least one active component for processing a high-frequency electromagnetic signal and coupled to the pad,
a pad opening layer, which extends at least partly on the active surface, said pad opening layer having an opening to the pad,
a contact distributor layer, which extends at least partly on the opening,
a passivation layer, which extends at least partly over the contact distributor layer and which has a second opening to the contact distributor layer, and
a contact to the contact distributor layer arranged on the second opening.

2. A semiconductor device according to claim 1, wherein a characteristic frequency of the high-frequency electromagnetic signal lies between 400 MHz and 5 GHz.

3. A semiconductor device according to claim 1, the circuit region comprising a modulator for modulating an information signal onto a carrier frequency signal.

4. A semiconductor device according to to claim 1, the circuit region comprising a demodulator for demodulating an information signal from a carrier frequency to baseband.

5. A semiconductor device according to to claim 1, wherein the circuit region comprises a power amplifier.

6. A semiconductor device according to claim 1, wherein the pad opening layer and the passivation layer each comprise a dielectric thin layer.

7. A semiconductor device according to claim 1, wherein a protective layer extends on the second surface of the substrate.

8. A method for producing a semiconductor device comprising:
Providing a substrate having an active surface and a second surface,
Forming a circuit region in the substrate, wherein the circuit region has at least one active component for processing a high-frequency electromagnetic signal,
Forming a pad opening layer having an opening over a pad of the substrate,
Forming a contact distributor layer, which extends at least partly on the opening of the pad opening layer,
Forming a passivation layer having second openings over a section of the contact distributor layer,
Arranging a contact on the second opening.

9. A method for producing a semiconductor device according to claim 8, comprising:
Thinning the substrate by grinding the second surface.

10. A method for producing a semiconductor device according to claim 8, comprising:
Applying a protective layer on the second surface of the substrate.

11. A semiconductor device comprising:
a substrate having an active surface and a pad arranged at the active surface,
a circuit region provided in the substrate, having at least one active component for processing a high-frequency electromagnetic signal and coupled to the pad,
a pad opening layer extending on the active surface of the substrate, said pad opening layer having an opening on the pad, and
a contact arranged on the opening.
